(19) United States
(12) Patent Application Publication
(10) Pub. No.: US 2009/0315169 A1
(43) Pub. Date: Dec. 24, 2009

(54) FRAME AND METHOD OF MANUFACTURING ASSEMBLY

(75) Inventor: Johannes W. Weekamp, Beek En Donk (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/373,044

(22) PCT Filed: Jul. 10, 2007
(86) PCT No.: PCT/IB07/52727

§ 371 Date: Jan. 8, 2009

(30) Foreign Application Priority Data
Jul. 20, 2006 (EP) 06117567.5

(51) Int. Cl. H01L 23/48; H05K 7/02; H01L 21/50

(52) U.S. Cl. 257/692; 361/809; 438/106; 438/456; 438/458; 257/E21.499; 257/E23.01

(57) ABSTRACT

The frame (1) comprises an intermediate layer (5) sandwiched between a first layer (3) with a first pattern and a second layer (4) with a second pattern. Adhesion layers (2,12) are present on the first and second layer (3,4) respectively. The patterns are defined such that bumping portions (31) and a cap (21) are defined. The intermediate layer (5) is continuous and extends over spaces (25) between bumping portions (31) and the cap (21), so as to prevent disintegration. The frame is assembled to a device (50) with an electronic element (52), such as a MEMS element. The cap (21) then encapsulates a cavity (60) over the element (52).

### FIELD OF THE INVENTION

The invention relates to a frame for use in assembly of electronic devices.

The invention also relates to a method of manufacturing an assembly, wherein such a frame is assembled to a device comprising at least one electronic element.

The invention further relates to the manufactured assembly.

### BACKGROUND OF THE INVENTION

A particular application of the invention relates to assemblies with electronic elements that need to be located in cavities with a closed cap. This location is needed due to the peculiar structure of the electronic element; examples of such elements are surface acoustic wave (SAW) filters, bulk acoustic wave (BAW) filters, microelectro-mechanical system (MEMS) elements, such as resonators, oscillators, tunable capacitors and switches and further certain display elements. Such elements have a movable structure or a surface that may not be covered with a mould.

It turns out that the manufacture of such assemblies is difficult, if all requirements are taken into account. The cap should provide protection against moisture, dust. It need to be mechanically stable and should not fail in thermal cycling due to large differences in thermal expansion between the cap and the device. Suitably, the cap is assembled to the device on a wafer-level scale, in order to reduce costs. For many applications, solder flux cannot be used, as it will pollute the electronic element, which leads to malfunctioning. For certain applications, such as RF MEMS capacitors, the atmosphere in the cavity should be conditioned, e.g. pure nitrogen, or the cavity must be put under vacuum. Certainly then, a hermetic encapsulation is needed. And in any case, the number of photolithographic steps is to be limited as much as possible, so as to limit assembly costs to an acceptable level—the assembly tends to be more expensive than the device manufacture. Suitably, the assembled device can be tested prior to dicing, and the assembly may be removed and repeated, if it does not meet the required test results. And this all must be achieved with a process that can be industrialized and used in large scale.

Overall, this is a real engineering challenge, and many proposals are put forward and developed in the hope that at least one process will meet all requirements. One is a proposal from IMEC as disclosed in U.S. Pat. No. 6,297,072. Herein, the cap is a silicon wafer that is provided with a ring of solder to the device. An indent in the solder ring allows to exchange the atmosphere within the cavity. However, one needs solder flux to make this work, which will damage the element in the cavity. Another proposal is disclosed in US2005/0067688 from Tessera. Herein, a frame, generally another wafer of glass, silicon or ceramics, is attached to a device wafer with an adhesive or the like. This adhesive is applied adjacent to the sensitive device structure. The frame is provided with through-holes that have metallized sidewalls. Solder balls are applied to such through-holes and melted. This melting causes a flow of solder downwards to extend to aligned contact pads on the device. An electrical connection between the frame and the device is the result. The protection offered by the cap of this patent application depends however on the material of the adhesive, which forms the side wall of the cavity. If the adhesive is a glass, it will be fine, but a polymer is often insufficient. A disadvantage of a glass is the high temperature needed to achieve a tight bond to ceramics, silicon or other glass. Another practical problem appears the needed alignment: if the frame is anywhere on the device wafer a bit misaligned, the solder may drop on other features than expected, with the consequence of failure.

EP-A 1445861 discloses another and rather straightforward proposal. The frame is here a substrate with conducting vias. The substrate can be of electrically insulating material, i.e ceramic or of electrically conducting material, i.e. metal, with an insulating surface. The frame is provided with a tin plating, the device is provided with a gold plating. These are fused in the bonding step. Herein both a sealing ring and individual contacts are established between the device and the frame. It is stated herein that the frame with a metal core and an insulating surface is preferred, since the thermal expansion coefficients of the device and the frame can be matched. However, such a matching makes the frame a very specific component, which is therefore expensive. Moreover, separation of the assembly into individual pieces requires dicing through both the device wafer and the metal core. Such a dicing operation is rather difficult with sawing, in view of the difference in hardness between the metal and the device. Evidently, the metal could be etched in a separate step, but this requires photolithography, which makes it again expensive.

Resuming, there is a need for an improved manufacturing method of such assembly, that is able to meet the requirements of cost and performance, and is suitably similar to other assembly processes so as to make use of standardized materials and processes.

### SUMMARY OF THE INVENTION

It is therefore a first object to provide an improved frame of the kind mentioned in the opening paragraph, which is suitable for the manufacture of assemblies comprising a cavity with a closed cap.

It is a second object to provide a manufacturing method of the kind mentioned in the opening paragraph, in which the frame is assembled with the device to form an improved assembly.

The first object is achieved in a frame comprising a first layer with a first pattern, an intermediate layer and a second layer with a second pattern, and wherein the intermediate layer is continuous, so that the carrier substrate does not disintegrate.

The second object is achieved in that this frame is assembled to the device, which device is thereto provided with contact pads in a pattern corresponding to at least part of the first pattern, which method comprises the steps of (1) aligning the contact pads of the device with at least part of the first pattern of the frame; (2) bonding the contact pads to said aligned patterns, and (3) etching of the intermediate layer.

The method of the invention is different from that of the prior art, in that both a cover portion and a wall portion of the cap are defined in the frame, instead of merely the cover portion. In other words, the structure of the cap can be predefined and there is merely the task of aligning and bonding during the assembly. The provision of the structure of the cap within the frame is enabled by the multilayer construction of the frame, which allows separate patterning of first and second layer.

The specific multilayer construction with a continuous intermediate layer allows integrity of the frame as long as such integrity is needed for mechanical stability. The construction moreover solves the problems of separation as present in the metal/resin embodiment of EP1445861, as explained above. This feature is evidently of advantage for more applications than merely the cap embodiment.

A further feature of the frame resides therein that the continuous intermediate layer has another constitution than the first and the second layer. This is needed in order to pattern the first and second layers independently of each other and without destroying the integrity of the frame. It moreover has the important advantage that the intermediate layer may absorb differences in thermal expansion between the device and the second patterned layer during bonding of the frame to the device. Due to the flexibility of the intermediate layer, neighboring portions (f.i. neighboring caps) behave thermomechanically independent. Warpage is then prevented or at least reduced to a minimal, functionally not problematic level. This absorption property is particularly important if the second pattern comprises laterally extended features, which connect features on different locations in the first pattern, such as with a cap.

It is observed that a frame with the constituent layers of first metal layer, intermediate layer and second metal layer is known per se from WO-A 03/85728. It is however not disclosed therein that the intermediate layer is continuous and both the first and the second layer have been patterned prior to assembly. In the prior art, the second layer and the intermediate layer of the frame are patterned before the assembly step. Thereafter the frame and device are overmolded to provide the mechanical stability. Finally the first layer is patterned through an etch mask thereon that also functions as an adhesion layer. In the present invention, no step of overmolding is needed for mechanical integrity.

In an advantageous embodiment, the first and the second layer comprise a metal or alloy and the intermediate layer is electrically conductive, and the first and second layer are each provided with a conductive adhesion layer at their sides remote from the intermediate layer. Suitably, the intermediate layer also comprises a metal or alloy. This embodiment is not merely suitable as a frame with such constituent layers is made available through the industrialization of the developments disclosed in the above-mentioned WO-A 03/85728. It has the further advantage, that a vertical interconnect can be provided—and without the definition of through-holes, the use of a flowing solder or other advanced and expensive features. A metal cap is moreover an excellent example of a hermetic package.

In an alternative embodiment, the first and second layers are made of a semiconductor material, such as silicon, or of an insulating material such as glass. The intermediate layer is then suitably a metal such as nickel. The semiconductor substrate may be patterned with wet or plasma etching, such as known for the definition of trenches and through-hole vias. Alternatively, a technique such as powder blasting may be used, particularly if the intermediate layer comprises a metal that is resistant to this technique. Nickel is such a material. Several techniques are in principle available for the formation of a mechanical connection between semiconductor substrates, including the use of solder or metal bumps, the use of an adhesive, the use of wafer bonding techniques and also the use of vapour deposition techniques (LPCVD deposition of nitride or polysilicon). It may be suitable to provide a suitable adhesion layer on at least the first layer prior to assembly. Such vapour deposition techniques need not to be excluded in view of a thermal budget, since the element in the cavity, such as a MEMS element preferably comprises materials with a thermal stability above 400° C.

The use of semiconductor materials for the first and second patterns has several advantages, particularly for the embodiment of the cap of a cavity package. First of all, there is no difference between device and cap with respect to the coefficient of thermal expansion. The packaged device is therefore able to withstand thermal cycling, which is an important issue in packaging. Secondly, the use of semiconductor substrate allows the continuation of processing in a semiconductor factory after the assembly step; in fact such assembly step could be carried out in or near a semiconductor factory. This is advantageous for logistic reasons and it opens a road to further system-in-package solutions. Thirdly, further functional elements may be defined in the semiconductor substrate. Such functional elements are largely known per se to the skilled person. Examples are transistors, diodes, capacitors, inductors and resistors in several modifications. The integration therein of a passive network of diodes, capacitors, inductors and resistors appears most appropriate. Specific use is the integration of diodes for ESD protection, the use of trench capacitors for decoupling purposes, the use of resistors, capacitors and inductors for the creation of filters. Most suitable is the use of a technology known from WO-A 04/114397. It is even possible to integrate passive portions of a DC-DC converter into such a substrate. This would allow for local conversion of the supply voltages to values needed for the driving of any MEMS or other element within the cavity. Additionally, vertical interconnects may be defined through the frame. It is therefore highly advantageous that the intermediate layer is electrically conductive. It may then act as a plating base for the provision of the conductive material in the vertical interconnects. It will be understood that such plating may not change the properties of those portions of the intermediate layer that are to be removed after assembly to the device.

The use of glass for the patterns has the advantage, that it may be integrated in other process flows that have been industrialized. Particularly, it may be integrated in a Shellcase package, such as known per se from WO-A 95/19645 and in a substrate transfer package construction, such as described in the non-prepublished application PH000 1717 (PCT/IB2006/052109). These applications are included herein by reference. Evidently, glass may be used for the one layer, while a semiconductor material is used for the other of the first and second layers.

Advantageously, the intermediate layer comprises a ductile metal or alloy. This is for instance a metal or alloy containing an element chosen from the group of Ni, Co, Fe, Ta, Mb, Pt, Pd, W. Most suitably, the Young's modulus is in the range of 100.10⁹-300.10⁹ Pa. Such materials are sufficiently ductile to allow deformation so as to compensate for difference in thermal expansion. Simultaneously, these materials are sufficiently rigid so as to prevent disintegration of the frame prior to assembly. Most suitably, the Young's modulus is in the range of 150-250.10⁹ Pa. Most suitably, use is made of a metal or alloy on the basis of Ni, Co or Fe. Such an intermediate layer is suitably used in combination with first and second layers of copper or a copper alloy, and has an adequate mechanical stability and ductility when applied in a suitable thickness. It moreover can be etched selectively to the metals of the first and the second pattern. Its exposure to air does not lead to corrosion.

In an even further modification, the intermediate layer has a thickness in the range of 0.1 to 10 micrometers. The upper limit of this thickness range is set by the method of removal of the intermediate layer where it extends from the patterns—an advantageous manner is etching, as this can be done maskless and on waferscale. The feature size further plays a role; as it cannot be excluded that some underetch of the first layer will occur, the underetch must be limited. The limitation of underetch should be such that underetch does not affect the mechanical stability and/or the electrical and/or thermal resistance negatively. The smaller the feature size, the sooner this limitation plays a role, and thus the lower the upper limit to the thickness of the intermediate layer. The lower limit of the range is set by the required consistency and mechanical stability of the intermediate layer, prior to assembly. This is evidently also dependent on the material of the intermediate layer. Very suitable is a thickness in the range of 0.5 to 5 micrometers, most suitable a thickness in the range of 1 to 3 micrometers. This is particularly the case for thicknesses of the first and second layer and minimum feature sizes in the order of 20-30 microns (i.e. at least a factor of 10 more).

Suitably, the first pattern comprises a closed ring-shaped wall portion and the second pattern comprises an extending cover portion, which on projection overlaps with the ring-shaped portion, therewith defining a cap in the frame. This is the embodiment for protection of a cavity. It has all advantages as mentioned above.

Moreover, a cap of the present invention appears to have adequate mechanical stability. Experiments with the metal version of the cap show that it has a span width of up to 500 micrometer, while it is nevertheless able to withstand the pressure of overmoulding in a transfer moulding process. A larger span width could be achieved, but then it is preferred to add pillars inside the cavity. And in case that the first pattern is defined by wet-chemical etching through the etch mask, its diameter will be larger at the interface with the intermediate layer than at the side remote therefrom. This inherently results in an inherently stronger mechanical construction.

In another advantageous embodiment, the first and second pattern each comprise an isolated area that when viewed in top view overlap with each other so as to form a bump-shaped interconnect. The invention is herein structurally different from the prior art EP 1445861. The interconnects or bumps from device to frame were defined inside the cavity. The bumps are defined outside the cavity and outside the cap in the present invention. An advantage hereof is that the cap size may be reduced, which further reduces thermal cycling problems.

As mentioned before, a benefit of the frame of the present invention is its possibility for reuse. This allows the use of standardized materials, which is important for cost reduction. In one embodiment the first and second pattern each comprise a grid array of mutually isolated areas that when viewed in top view overlap with each other so as to define a ball grid array. Ball grid arrays are currently provided with the help of individual solder balls, which need to be placed on the contact pads individually. Not merely the balls but also this one-by-one placement constitutes an important factor in the costs of a ball grid array package. The alternative of stud bumps requires photolithographical processes and wet chemistry (e.g. plating), and is not always possible The use of the present frame as a sheet with a ball grid array appears to provide an interesting, cost-effective alternative that is easy in use. The device to which the frame is attached is in this case suitably the carrier substrate of a package, or also a plurality of devices as in the case of wafer level chip scale packaging. Attachment of frame and device can be achieved relatively easy with a thin solder layer, or in the manner disclosed in EP1445861 by diffusion bonding of surface layers present on the device and on the frame (such as Sn and Au, Ag and Au, Au and Al, Au and Au). If any solder is applied, its thickness is suitably less than 20 microns and preferably less than 10 microns.

In an interesting modification hereof, the array has a pitch between neighboring areas that is smaller than a height between the first and the second etch mask of the frame. It is known to the skilled person in the field of soldering that the pitch of solder balls is related to the diameter of the solder balls, and that the diameter determines the distance between the device and a carrier substrate. This distance is important for the behavior in thermal cycling: a larger distance, also referred to as stand-off height, reduces problems in thermal cycling. Due to the constitution of the frame of the invention, the pitch may be reduced without reduction of the stand-off height.

In another embodiment, the frame can be used for definition of an inductor in a package. This idea of the inventor, implemented in a somewhat different technology, has been disclosed in WO-A 03/85729. The disclosed technology is a two-layered foil with a sacrificial layer and a patterned layer. The advantage of the present invention over the disclosed implementation first of all resides in the processing: the needed etching time may be substantially reduced. Moreover, definition of bumps for connection between the device and the inductor is simplified with the present invention.

In a further embodiment, the frame may be used to define contact pads more adequately, for instance for devices that are located in cavities. This example is for instance disclosed in WO-A 03/85736, again in an earlier technological version. Alternatively, it may be used to bring certain contact pads to a higher level. This might be useful in order to carry out assembly processes on two different levels. For instance wirebonds from device to package substrate are applied to the non-elevated contact pads, while wirebonds from a first device to a second neighboring device in the same system-in-package are provided from the elevated-contact pads. Alternatively, the non-elevated contact pads may be used for wirebonding, while the elevated contact pads are used for placement of a further device in a stacked die configuration.

In an even further embodiment, the frame may be bent prior to assembly and used to provide conductors in a package extending in a third dimension relatively to the plane of the device. Applications on the basis of a similar technology, e.g. a two layered foil with a sacrificial layer and a patterned layer, have been described in applications before. Such applications include, among others, the use for clip bonding and the use for a plurality of wirebonds, for instance around a ferromagnetic core.

Although the previous applications have been largely mentioned as separate examples, it is not excluded to use those in combination with each other. Furthermore the frame may be used for interconnect or rerouting purposes. In this case, at least one of the first and the second patterns comprises laterally extending portions to function as interconnects or rerouting tracks. Furthermore, the frame may further include heatsink features or die pad features. It is herein not excluded that a cap-alike structure is used to attach a chip in a buried position.

The assembly method of the invention is most suitable carried out on wafer level, in the sense that not merely the frame comprises a plurality of units, but that also the device is part of a body comprising a plurality of devices. Such wafer level assembly is advantageous from the perspective of costs, while the performance of the intermediate layer allows compensation of differential thermal expansion between the devices and the frame.

The body is suitably a body of semiconductor material in case the devices comprise elements with movable portions such as MEMS-elements or elements with sensitive surfaces such as Bulk Acoustic Wave (BAW) elements.

The body could alternatively be a carrier substrate of a package. This is suitable with the embodiment of the ball grid array, wherein most suitably the carrier substrate has been overmoulded prior to the assembly step. It is furthermore suitable for the manufacture of cavities around discrete elements, such as discrete power semiconductor elements and image sensors. In the example of power semiconductor elements, the element is suitably positioned on top of a heat sink. Examples of such elements are vertical DMOSTs, bipolar transistors, lateral DMOSTs for RF power applications. Electrical connections to contact pads on the element are made with a wirebonding or a clipbonding technique. Furthermore, the element may be provided with a thermal connection to the cap of the cavity. This is particularly preferred, if the element is assembled to the substrate with a flip-chip technique. The cap may then serve not only as a thermal connection, but also as an electrical connection.

It is however not excluded, that the assembly method is carried out such that a plurality of singulated devices is assembled to a single frame.

The invention further relates to the resulting assembly of an individualized portion of the frame and a device. As will be understood by the foregoing, several embodiments of such an assembly are envisaged. Without repeating all features and options in detail, it will be understood that these features also apply to the resulting assembly. One advantage of the assembly of the invention is its uniformity. The assembly process comprises merely a limited number of separate steps, and makes use of a frame, which is predefined for a plurality of components. This implies that the margin of tolerances as a result of the assembly is rather small. Another advantage of the assembly is the limited level of inherent stresses. Due to the enabled stress release on the basis of the continuous intermediate layer of the frame, the build up of stress in the assembly is reduced. This improves reliability.

### BRIEF DESCRIPTION OF THE DRAWINGS

These and other aspects of the frame, the method and the assembly of the invention will be further elucidated with reference to the Figures, in which:

FIG. 1 shows in cross-sectional view the frame prior to etching of the first and second layers and as known in the prior art;

FIG. 2 shows in cross-sectional view the frame of the invention after etching of the first and second layers;

FIG. 3 shows in cross-sectional view an electronic device to which the frame is assembled;

FIG. 4 shows in cross-sectional view the assembly of device and frame

FIG. 5 shows in cross-sectional view the assembly after removal of certain portions of the intermediate layer;

FIG. 6 shows the frame and the device with the solder depot, and

FIG. 7 shows the resulting assembly in a bird's eye perspective.

### DETAILED DESCRIPTION

The Figures are not drawn to scale and equal reference numerals in different Figures refer to like parts.

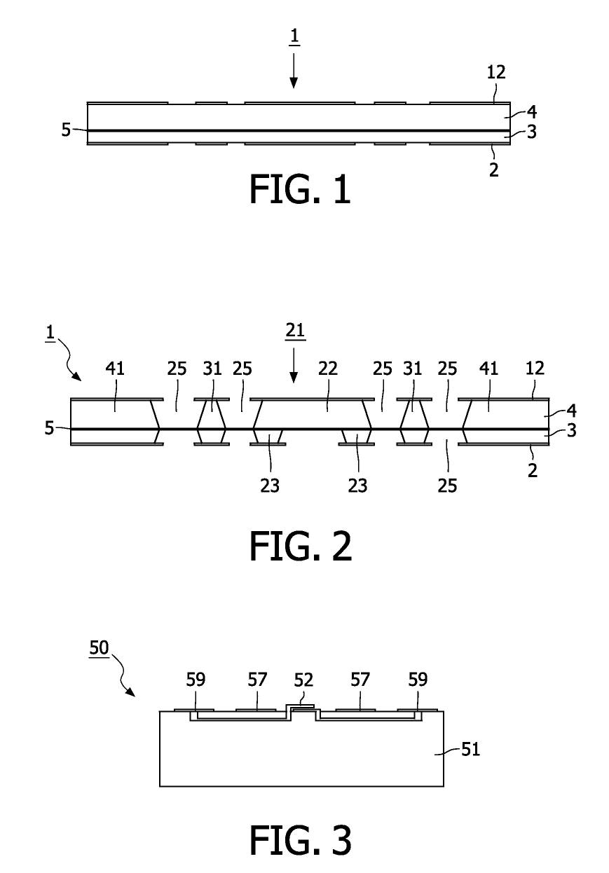

FIG. 1 shows in cross-sectional view the frame 1 prior to definition of the first and the second patterns in the first and the second layers. The frame 1 comprises a first layer 3, an intermediate layer 5 and a second layer 4. The first layer 3 comprises copper and has a thickness of 25 microns. The second layer 4 also comprises copper and has a thickness of 65 microns. The intermediate layer 5 comprises nickel and has a thickness of 1 micron. It will be understood that these are merely exemplary examples. It however appears advantageous that the first layer 3 has a smaller thickness than the second layer 4. This is particularly the case, when the second layer 4 has patterns that extend laterally, such as a cover portion of a cap. The thickness of the second layer 4 has an impact on its mechanical stability. This is clearly relevant for a cover portion in case that the assembly is overmoulded. Suitably, the second layer 4 does not have a thickness that is more than four times as thick as the first layer 3. I.e. with a first layer 3 of 25 microns, the second layer 4 is suitably not thicker than 100 microns. Advantageously, the ratio is at most 3. A too large difference in ratios results in differences in resolution, which appear less adequate from a design perspective. The thickness of the example allow a linewidth of 50 microns in the first layer 4 with a pitch of 100 microns. This is clearly about the resolution in current ball grid array packages, where a pitch of 500-1000 microns is conventionally used.

An adhesion layer 2 is provided on the first layer 3, remote from the intermediate layer 5. An adhesion layer 12 is provided on the second layer 4, remote from the intermediate layer 5. The adhesion layers 2,12 of this example comprise a stack of nickel, palladium and gold, but that is not essential. As is clear from the Fig., the adhesion layers 2, 12 have been provided with a first and a second pattern respectively, which first and second pattern are different. The patterns are to be transferred to the first and second layer 3,4 respectively by etching.

FIG. 2 shows the frame 1 of the invention after the patterning of the first and the second layers 3,4 according to the patterns in the adhesion layers 2,12. The specific patterns provide a cap 21, having a cover portion 22 and a ring-shaped portion 23. Bump portions 31 are present adjacent to the cap portion 21. Additionally, frame portions 41 are shown. These frame portions 41 are suitably present on the lateral edges of the frame for handling purposes. In practice, the frame portions 41 will surround a plurality of individual units within the frame 1. Another bump portion 31 or cap 21 will then be present adjacent to the shown bump portion 31. Spaces 25 are present between the individual portions 21, 31, 41 of the frame. The portions 21,31,41 are mutually connected with the continuous intermediate layer 5, which therefore ensures that the frame 1 does not fall apart into said portions 21,31,41.

The adhesion layers 2,12 have a larger lateral extension (i.e. surface area) than the corresponding portions of the first and second layers 3,4, as a consequence of underetching. This is believed to be advantageous, in that the larger surface area also provides an improved adhesion to corresponding contact pads in the device to be assembled or in an external component or board. It will be understood that the frame 1 can also be provided with other features than a cap 21 or bump portions 31. The features depend on the first and second pattern. It allows the provision of interconnect patterns, the provision of a grid array of bump portions, the provision of inductors and the like. Laterally extending lines are suitably defined in the second layer 4, in view of its larger thickness, and in order to use contact pads of limited size to any device.

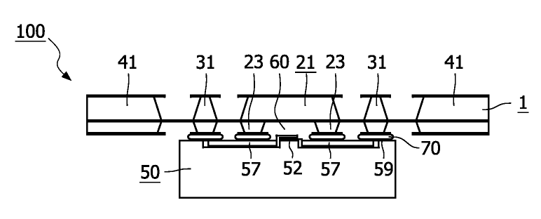

FIG. 3 shows the device 50 that can be assembled with the method of the invention. This device 50 is provided with a substrate 51 and comprises an element 52, which is a micro-electromechanical systems (MEMS) element in this example. The MEMS element 52 of the present example is a capacitive MEMS element that is manufactured in a thin film technique. Evidently, this is not essential and other MEMS elements such as MEMS elements suitable as resonator or accelerometer, which are defined in a polycrystalline layer or in a substrate layer, are not excluded. The device 50 is further provided with a ring-shaped contact pad 57 and with interconnect pads 59.

FIG. 4 shows the assembly 100 of the invention after the execution of the method of the invention. According to this method, the frame 1 is first aligned to the device 50. Herein, the ring-shaped portion 23 of the frame 1 is aligned with the ring-shaped contact pad 57 of the device 50. Additionally, the bump portions 31 of the frame 1 are aligned with the interconnect pads 59 of the device 50. The latter operation is not essential for the provision of the cap around the cavity 60, but it is very suitable. The alignment may be carried out with the help of optical alignment masks, if needed.

Subsequently, the mentioned portions 23,31 of frame 1 and the pads 57,59 of the device 50 are bonded to each other. Use is made, in this example, of solder material 70 applied either on the pads 57,59 or on the portions 23,31 or on both. Particularly, use is made of a flux free soldering process, for instance with gold/tin. Although a flux-free soldering process needs a higher soldering temperature, it does not damage the MEMS element 52 in the cavity 60. Such a higher soldering temperature is for instance a temperature in the order of 280° C. It has the benefit, that the cavity 60 is hermetically encapsulated by the combination of the cap 21, the device 50 and the solder material 70. It will however be understood that there are alternatives for the flux-less solder application with additional solder material 70. One such example is the diffusion soldering mentioned in EP1445861. Another is the use of immersion soldering bumps, which preferably have been applied on the frame. The application on the frame is preferred as one needs an immersion step in a liquid bath. This immersion step would damage a MEMS element and does not appear appropriate for any other sensitive surface or for a carrier substrate to which chips have been assembled (and wirebonded). In case of use of immersion soldering bumps, the adhesion layer 2 suitably primarily consists of nickel.

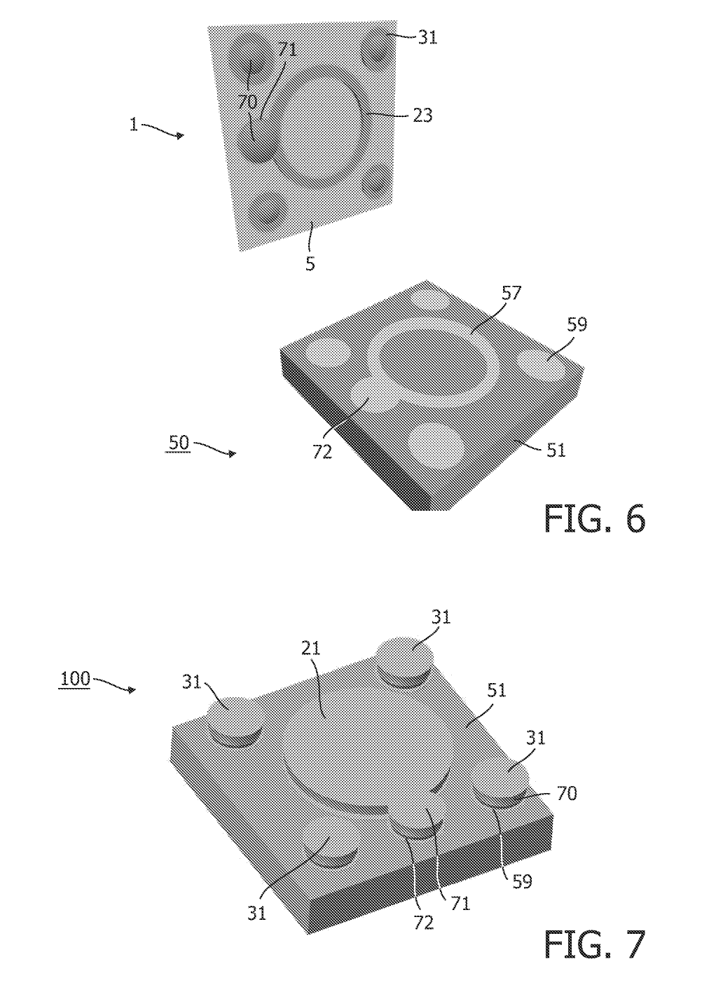

FIG. 6 shows the frame 1 and the device 50 prior to assembly in a bird eye's perspective. It can be seen in this Figure that the solder 70 is applied to the frame 1. A specific solder deposit 71 is defined on the frame 1. This deposit 71 is connected to the ring-shaped portion 22. A corresponding feature 72 is defined in the device 50. After deposition of the solder material 70 on the solder deposit 71, a reflow step and a cleaning step are carried out. Thereafter, the alignment and bonding steps will take place. The bonding occurs in that the frame 1 and the device 50 are aligned and positioned such that the solder material 70 completely or nearly touches the feature 72. The temperature is then increased. Due to the limited distance between the frame 1 and the device 50, the solder material will start to flow and wet the complete ring-shaped portion 22 as well as the corresponding pad 57.

FIG. 5 shows the resulting assembly 100 after removal of parts of the intermediate layer 5. FIG. 7 shows the same assembly in an isometric view. The removed parts are those present in the spaces 25 between the portions 21,31,41 of the frame 1. The assembly 100 may be overmoulded subsequently. Alternatively, an insulating material may be applied otherwise, such as by spincoating, or the spaces 25 between the portions 21,31 may be left empty. The assembly 100 may be attached to an external component, such as a printed circuit board, using the adhesion layer 12 on the second layer 4 of the frame 1.

In short, the invention provides a frame, and method of assembly the frame. The frame (1) comprises an intermediate layer (5) sandwiched between a first layer (3) with a first pattern and a second layer (4) with a second pattern. Adhesion layers (2,12) are present on the first and second layer (3,4) respectively. The patterns are defined such that bumping portions (31) and a cap (21) are defined. The intermediate layer (5) is continuous and extends over spaces (25) between bumping portions (31) and the cap (21), so as to prevent disintegration. The frame is assembled to a device (50) with an electronic element (52), such as a MEMS element. The cap 21 then encapsulates a cavity (60) over the element (52).

1. A frame for use in assembly of electronic devices comprising in consecutive order a first layer with a first pattern, an intermediate layer, a second layer with a second pattern, wherein the intermediate layer is continuous, so that the carrier substrate does not disintegrate.

2. A frame as claimed in claim 1, wherein the first and second layer are provided with an adhesion layer on their sides remote from the intermediate layer, which adhesion layers are also etch masks for the definition of the first and second patterns into the first and second layer.

3. A frame as claimed in claim 2, wherein the first and the second layer and the first and second adhesion layers comprise a metal or alloy and the intermediate layer is electrically conductive.

4. A frame as claimed in claim 1, wherein the first and second layer each comprise a material chosen from the group of glass and semiconductor materials.

5. A frame as claimed in claim 1, wherein the intermediate layer has a thickness in the range of 0.1 and 10 micrometer.

6. A frame as claimed in claim 1, wherein the first pattern comprises a closed ring-shaped portion and the second pattern comprises an extending portion, which on projection overlaps with the ring-shaped portion, therewith defining a cap in the frame.

7. A frame as claimed in claim 6, wherein the first and second pattern each comprise an isolated area that when viewed in top view overlap with each other so as to form a bump-shaped interconnect.

8. A frame as claimed in claim 3, wherein the first and second pattern each comprise a grid array of mutually isolated areas that when viewed in top view overlap with each other so as to define a ball grid array.

9. A frame as claimed in claim 8, wherein the array has a pitch between neighboring areas that is smaller than a height between the first and the second etch mask of the frame.

10. A frame as claimed in claim 6, wherein at least one of the first and the second patterns comprises laterally extending portions to function as interconnects or rerouting tracks.

11. A method of manufacturing an assembly, wherein a frame as claimed in any of the previous claims is assembled to a device comprising at least one electronic element which device is provided with contact pads in a pattern corresponding to at least part of the first pattern of the frame, which method comprises the steps of:
aligning the contact pads of the device with at least part of the first pattern of the frame;
bonding the contact pads to said aligned patterns, and
removing the intermediate layer so as to separate patterns in the frame.

12. The method as claimed in claim 11, wherein the frame as claimed in claim 6 is applied and the electronic element after the manufacturing located within the cap.

13. The method of claim 11, wherein the electronic element is chosen from the group of microelectromechanical system (MEMS)-elements, surface and bulk acoustic wave elements (SAW, BAW), and discrete power semiconductor elements.

14. The method as claimed in claim 11, wherein the bonding occurs with a flux-free solder.

15. The method as claimed in claim 11, wherein a solder depot is defined on at least one of the substrate and the frame, said solder depot is present on or aligned to a solder pad connected to a laterally extending portion of the first pattern, and wherein the solder covers said laterally extending portion in the first pattern by capillary action during the bonding step.

16. The method as claimed in claim 11, wherein the removal occurs by etching.

17. An assembly comprising an electronic device and individualized portion of a frame obtainable by a method as claimed in claim 11.

18. An assembly comprising an electronic device with a first element that is provided in a cavity enclosed by a cap, wherein the cap comprises a first layer with a first pattern, an intermediate layer and a second layer with a second pattern, wherein the first pattern is ring-shaped structure and the second pattern is an continuous area.

19. An assembly comprising an electronic device comprising at least one electronic element, which device is provided with a substrate having a first and an opposite, second side, on which first side the electronic element is present and on which second side a plurality of contact pads is defined to which bumps are attached, wherein the plurality of bumps comprise a first layer with a first pattern, an intermediate layer and a second layer with a second pattern, wherein the first and second layer each comprise a metal or alloy and the intermediate layer is electrically conductive, and wherein the first layer comprises an adhesion layer for connection to the contact pads on the substrate and the second layer comprises an adhesion layer for connection to contact pads on an external component.
